(19) United States
(12) Patent Application Publication
(10) Pub. No.: US 2026/0244829 A1
(43) Pub. Date: Aug. 20, 2026

(54) FLEET MONITORING SYSTEMS

(71) Applicant: Enphase Energy, Inc., Fremont, CA (US)

(72) Inventors: Sandeep PABBATHI, NagarKurnool (IN); Jinendra Kacharulal GUGALIYA, Mahadevapura (IN); Sumit SARAOGI, Fremont, CA (US); Chandan VERMA, Bengaluru, (IN)

(21) Appl. No.: 19/530,654

(22) Filed: Feb. 5, 2026

(30) Foreign Application Priority Data
Feb. 19, 2025 (IN) 202511014290

(51) Int. Cl. G06F 30/27

(52) U.S. Cl. CPC G06F 30/27

(57) ABSTRACT

An apparatus for monitoring fleet data is provided and comprises a simulation module configured to emulate site behavior for home energy management system (HEMS) profiles, an anomaly detection module coupled to the simulation module and configured to detect an anomaly at the site, and a corrective actions module coupled to the anomaly detection module and configured to provide corrective mechanisms to a user for the anomaly.

### CROSS-REFERENCE TO RELATED APPLICATIONS

The present application claims the benefit of and priority to Indian Provisional Application Serial No: 202511014290, filed on Feb. 19, 2025, the entire contents of which is hereby incorporated by reference.

### BACKGROUND

### 1. Field of the Disclosure

Embodiments of the present disclosure generally relate to fleet monitoring systems and, for example, to fleet monitoring systems that are configured to automatically detect anomalies at a site and automatically provide feedback for correcting the anomalies.

### 2. Description of the Related Art

Conventional power conversion systems (energy management systems) are very well known, and customer support (CS) solely through human agents (a CS team) is not a scalable solution and is not efficient due to the numerous amounts of information (fleet data) that is scattered across the tool chain, which is not easily available to the CS team in actionable format. For example, the CS team, typically, resolves problems only after users (customers) report the problems, which can be time-consuming. Additionally, fleet data is, typically, analyzed using one or more statistical methods, but analyzation of that type is only in reaction to field failures and/or customer cases.

Therefore, described herein are improved fleet monitoring systems that are configured to automatically detect anomalies at a site and automatically provide feedback for correcting the anomalies.

### SUMMARY

In accordance with some aspects of the present disclosure, there is provided an apparatus for monitoring fleet data that comprises a simulation module configured to emulate site behavior for home energy management system (HEMS) profiles, an anomaly detection module coupled to the simulation module and configured to detect an anomaly at the site, and a corrective actions module coupled to the anomaly detection module and configured to provide corrective mechanisms to a user for the anomaly.

In accordance with some aspects of the present disclosure, there is provided a method for monitoring fleet data. The method comprises emulating site behavior for home energy management system (HEMS) profiles, detecting an anomaly at the site, and providing corrective mechanisms to a user for the anomaly.

In accordance with some aspects of the present disclosure, there is provided a non-transitory computer readable storage medium having instructions stored thereon that when executed by a processor perform a method for monitoring fleet data. The method comprises emulating site behavior for home energy management system (HEMS) profiles, detecting an anomaly at the site, and providing corrective mechanisms to a user for the anomaly.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a diagram of monitoring and correction fleet system for use with the system for power conversion of FIG. 1, in accordance with at least some embodiments of the present disclosure;

FIGS. 3A and 3B are screenshots of a monitoring dashboard of the monitoring and correction fleet system of FIG. 2, in accordance with at least some embodiments of the present disclosure; and

FIG. 4 is a flowchart of a method for monitoring fleet data, in accordance with at least some embodiments of the present disclosure.

### DETAILED DESCRIPTION

As noted above, described herein are improved fleet monitoring systems that are configured to automatically detect anomalies at a site and automatically provide feedback for correcting the anomalies. For example, an apparatus for monitoring fleet data can comprise a simulation module that can be configured to emulate site behavior for home energy management system (HEMS) profiles. An anomaly detection module coupled to the simulation module can be configured to detect an anomaly at the site. A corrective actions module coupled to the anomaly detection module ca be configured to provide corrective mechanisms to a user for the anomaly. The inventive concepts described herein provide an online monitoring system that proactively identifies issues and suggests corrective actions, thus enabling the customer support team to respond more quickly and efficiently.

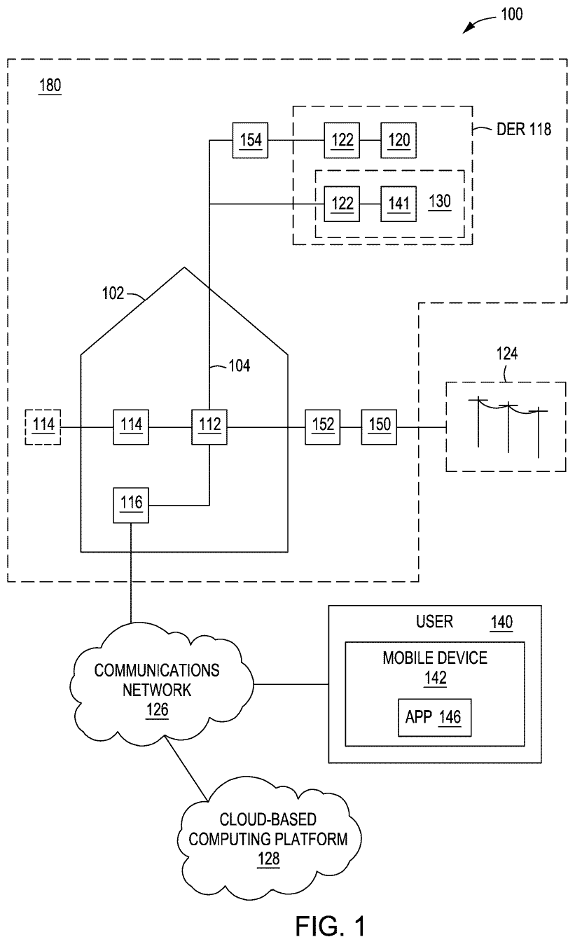

FIG. 1 is a block diagram of an energy management system (e.g., power conversion system, system 100) in accordance with one or more embodiments of the present disclosure. The diagram of FIG. 1 only portrays one variation of the myriad of possible system configurations. The present disclosure can function in a variety of environments and systems.

The system 100, which, for example, can be a home energy management system (HEMS), comprises a structure 102 (e.g., a user's structure, such as a home), such as a residential home, commercial building, or separate mounting structure, having an associated DER 118 (distributed energy resource). The DER 118 is situated external to the structure 102. For example, the DER 118 may be located on the roof of the structure 102 or can be part of a solar farm. Alternatively, the DER 118 can be situated internal to the structure 102. For example, when the DER 118 is a permanent residential battery energy storage system, the DER 118 may be installed in a garage (or other suitable location inside the structure 102). The structure 102 comprises one or more loads and/or energy storage devices 114 (e.g., portable energy systems (PES), appliances, electric hot water heaters, thermostats/detectors, boilers, electric vehicle supply equipment (EVSE), EVs, water pumps, and the like), which can be located within or outside the structure 102, and a DER controller 116, each coupled to a load center 112. Although the one or more loads and/or energy storage devices 114, the DER controller 116, and the load center 112 are depicted as being located within the structure 102, one or more of these may be located external to the structure 102.

The load center 112 is coupled to the DER 118 by an AC bus 104 and is further coupled, via a meter 152 (utility meter comprising a utility meter socket) and optionally a MID 150 (microgrid interconnect device), to a grid 124 (e.g., a commercial/utility power grid). The structure 102, the energy storage devices 114, DER controller 116, DER 118, load center 112, generation meter 154, the meter 152, and the MID 150 are part of a microgrid 180. It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122 (e.g., microinverter, power converter, power conversion units (PCUs), etc.). For example, the DER 118 may comprise a plurality of RESs 120 coupled to a plurality of power conditioners 122 in a one-to-one correspondence (or two-to-one). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one correspondence, where each pair of power conditioner 122 and a DC battery 141 may be referred to as an AC battery 130.

The power conditioners 122 invert the generated DC power from the plurality of RESs 120 and/or the DC battery 141 to AC power that is grid-compliant and couple the generated AC power to the grid 124 via the load center 112. The generated AC power may be additionally or alternatively coupled via the load center 112 to the one or more loads (e.g., EV, EVSE) and/or the energy storage devices 114. In addition, the power conditioners 122 that are coupled to the DC batteries convert AC power from the AC bus 104 to DC power for charging the DC batteries. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway that receives data (e.g., alarms, messages, operating data, performance data, and the like) from the power conditioners 122 and communicates the data and/or other information via the communications network 126 to a cloud-based computing platform 128, which can be configured to execute one or more application software, e.g., a grid connectivity control application and/or a fleet monitoring system, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application and/or a fleet monitoring system) for performing one or more of the functions described herein (e.g., the methods described herein).

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kWh) and, in some embodiments, reactive power flow (KVAR). The generation meter 154 may communicate the measured values to the DER controller 116, for example using PLC, other types of wired communications, or wireless communication. Additionally, battery charge/discharge values are received through other networking protocols from the DC battery itself.

The meter 152 may be any suitable energy meter that measures the energy consumed by the microgrid 180, such as a net-metering meter, a bi-directional meter that measures energy imported from the grid 124 and well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kWh), reactive power flow (KVAR), grid frequency, and grid voltage. The meter 152 measures power flows independently of MID state, i.e., when MID is closed and DER's are connected to the grid and when MID is open and DER's are isolated from the grid.

The MID 150, which may also be referred to as an island interconnect device (IID), connects/disconnects the microgrid 180 to/from the grid 124. The MID 150 comprises a disconnect component (e.g., a, relay, a contactor, or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication), and based on the received information (inputs), the DER controller 116 determines when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly, where the disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, or the like) communicably coupled by wireless means to the communications network 126. The mobile device 142 has a CPU, support circuits, and memory, and has one or more applications (e.g., a grid connectivity control application (an application 146)) installed thereon for controlling the connectivity with the grid 124 as described herein. The mobile device 142 may run on commercially available operating systems, such as IOS, ANDROID, and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, the scenarios below, listed in order of priority, will be managed differently. Based on the desired action as entered by the user 140, the corresponding instructions are communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

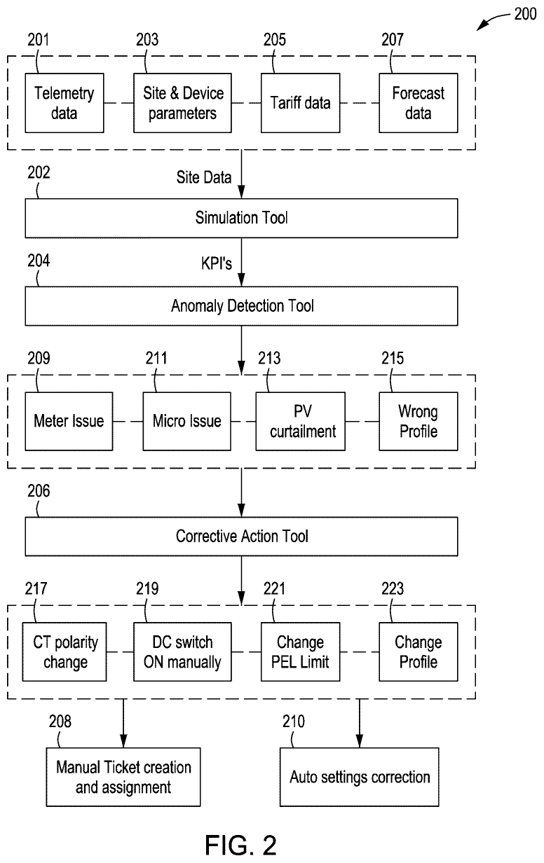

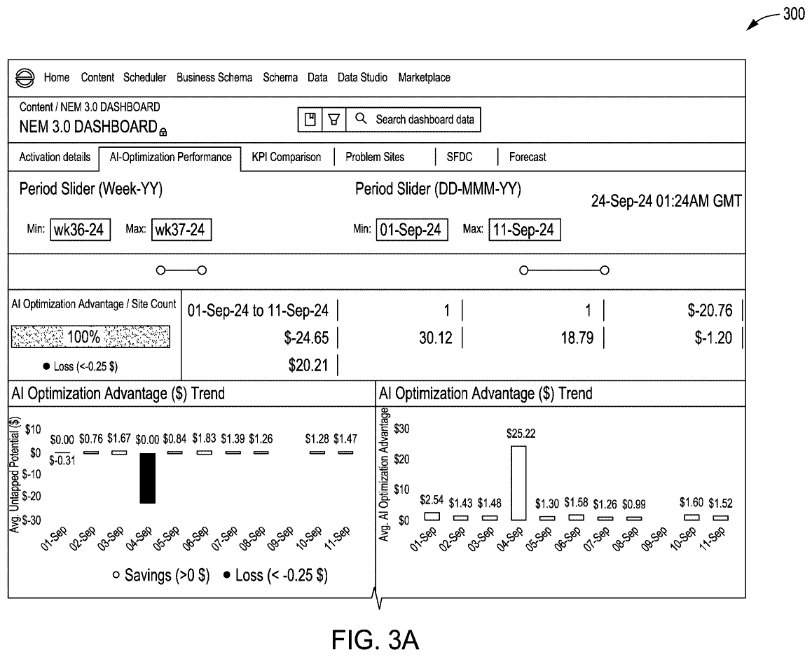

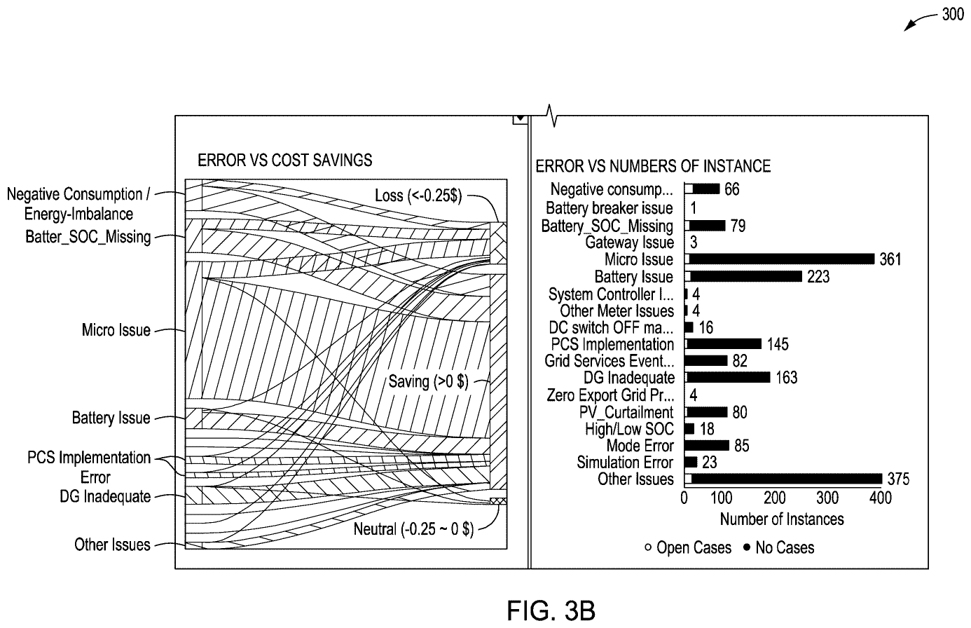

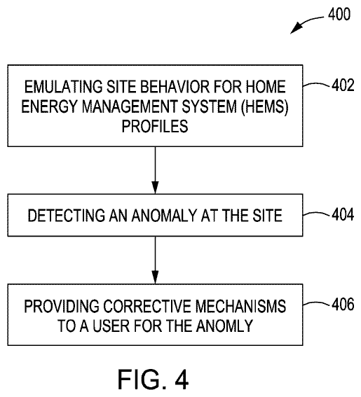

FIG. 2 is a diagram of a monitoring and correction fleet system (an apparatus 200) for use with the system for power conversion of FIG. 1, FIGS. 3A and 3B are screenshots of a monitoring dashboard 300 of the monitoring and correction fleet system of FIG. 2, and FIG. 4 is a flowchart of a method 400 for monitoring fleet data, in accordance with at least some embodiments of the present disclosure in accordance with at least some embodiments of the present disclosure.

For example, at 402, the method 400 comprises emulating site behavior for home energy management system (HEMS) profiles. For example, the apparatus 200 can comprise a simulation module 202 configured to emulate site behavior HEMS profiles. For example, the simulation module 202 is configured to receive site data from the system 100. In at least some embodiments, the site data can comprise one or more of telemetry data 201, site and device parameters 203, tariff data 205, or forecast data 207. The simulation module 202 performs a simulation of the system 100 using the site data and outputs key performance indicators (KPIs), which are quantifiable metrics that measure how well the system 100 is performing, e.g., the simulation module 202 uses the KPIs to evaluate the system 100. The simulation module 202 transmits the results to an anomaly detection module 204 coupled to the simulation module 202.

For example, at 404, the method 400 comprises detecting an anomaly at the site. For example, the anomaly detection module 204, which can be domain knowledge based or artificial intelligent/machine learning (AI/ML) driven based (such as the AI/ML apparatus/methods disclosed in commonly-owned Indian Provisional Application No. 202411067589, the entire contents of which is incorporated herein by reference), is configured to detect an anomaly at a site (e.g., the system 100). In at least some embodiments, the anomaly detection module 204 can be configured to detect one or more of meter anomalies 209, microinverter anomalies 211, PV anomalies 213, profile anomalies 215, and/or the anomalies listed in Table 1 or Table 2, as described below. The anomaly detection module 204 transmits the results to a corrective actions module 206 coupled to the anomaly detection module 204.

For example, at 406, the method 400 comprises providing corrective mechanisms to a user for the anomaly. For example, the corrective actions module 206, which can be domain knowledge based, is configured to provide corrective mechanisms to a user for the anomaly. In at least some embodiments, the corrective mechanisms can comprise one or more of changing a current transformer (CT) polarity (e.g., for meter anomalies), determining if a DC switch is on 219 (e.g., for microinverter anomalies), changing power export limit 221 (e.g., for PV anomalies), changing a profile 223 (e.g., for profile anomalies), Battery anomalies, and/or the corrective mechanisms listed in Table 1 or Table 2, as described below. The corrective actions module 206 can transmit the results to a work order generation module 208 (manual or automatic work order generation module) coupled to the corrective actions module 206.

For example, the method 400 can comprise generating/creating a ticket (e.g., work order) and assigning the work order to a respective team for correcting the anomaly. In such embodiments, the work order generation module 208 can be configured to create a work order and assign the work order to a respective team (e.g., a manual fix). Alternatively or additionally, the method 400 can comprise automatically correcting the anomaly. In such embodiments, an auto setting correction module 210 can be configured to automatically correct the anomaly (e.g., an automatic fix).

Table 1 lists inputs from the anomaly detection module, inputs from the corrective actions module, and suggested methods to correct the issue.

TABLE 1

| ANOMALY | CORRECTIVE ACTION | METHOD |
|---|---|---|
| negative consumption/energy | fix consumption/battery current | Manual fix |
| imbalance | transformer (CT) issues | |
| site status error including at least | customer experience (CX) team | Manual fix |
| one of battery SoC missing, micro | should assist a customer in | |
| issue, battery issue, gateway | resolving device-level issues | |
| issue, system controller issue, or | | |
| dc switch off manually | | |
| high/low soc | fix battery issue | Manual fix |
| breaker issue comprising wrong | correct pcs settings | Automatic fix |
| pcs breaker sizing | | |
| SoH issue | correct SoH value through | Automatic fix |
| | calibration | |
| distributed generation (DG) | fix communication issue between | Automatic fix |
| inadequate | enlighten and envoy | |
| photovoltaic (PV) curtailment | change power export limit (PEL) | Automatic fix |
| | settings higher than zero | |
| recommended for SC + DTG | change profile to self-consumption | Automatic fix |
| | DTG from Al optimization mode | |
| forecast error | improve accuracy of forecasts | Automatic fix |

Table 2 lists one or more examples of use of the apparatus 200, which can be programmed with instructions to perform the method 400 for monitoring fleet data.

TABLE 2

| WHAT IS THE CASE | HOW IS IT IDENTIFIED | HOW IS IT ADDRESSED | HOW IS IT FIXED |
|---|---|---|---|
| The site has been | Dashboard displays data | After an in-depth analysis, | Temporarily change the |
| underperforming for the past | over 7k+ sites. | the root cause has been | profile to self-consumption |
| few days | Based on the KPIs | identified and it is related to | DTG until the |
| | generated by the simulation | an issue with | communication gateway |
| | tool, the dashboard | communication gateway | issue is resolved |
| | indicates that site falls under | (e.g., clock skew problem) | |
| | DG inadequate issue in | and communication network | |
| | peak hours. | issue. | |
| | | The following ticket shows | |
| | | work progress on this issue | |
| The site has been | Based on the KPIs | After analysis, it was found | Change the default mode |
| underperforming for the past | generated by the simulation | that PV curtailment is | of the HEMS schedule to |
| few days | tool, the dashboard | occurring due to the default | ZN, instead of ZN + zero |
| | indicates that the site falls | schedule being set to zero | export |
| | under PV curtailment issue. | export | |
| | | The following ticket shows | |
| | | work progress on this issue | |
| | | zero export mode | |
| The site has been | Based on the KPIs | Inaccuracy of consumption | Work on improving |
| underperforming for the past | generated by the simulation | forecast in peak hours | forecast accuracy |
| few days | tool, the dashboard | leading to suboptimal | |
| | indicates that the site falls | schedule. | |
| | under Forecast Error issue. | The following ticket shows | |
| | | work progress on this issue | |
| | | Forecast issue | |

In at least some embodiments, the method 400 can comprise receiving an input from one or more of the simulation module 202, the anomaly detection module 204, and/or the corrective actions module 206 and displaying the information from the one or more of the simulation module 202, the anomaly detection module 204, and/or the corrective actions module 206 on a monitoring dashboard, see the screenshots of FIGS. 3A and 3B, for example.

While the foregoing is directed to embodiments of the present disclosure, other and further embodiments of the disclosure may be devised without departing from the basic scope thereof, and the scope thereof is determined by the claims that follow.

1. An apparatus for monitoring fleet data, comprising:
a simulation module configured to emulate site behavior for home energy management system (HEMS) profiles;
an anomaly detection module coupled to the simulation module and configured to detect an anomaly at a site; and
a corrective actions module coupled to the anomaly detection module and configured to provide corrective mechanisms to a user for the anomaly.

2. The apparatus of claim 1, further comprising at least one of a manual or automatic work order generation module configured to assign a work order to a respective team.

3. The apparatus of claim 1, wherein the anomaly detection module is at least one of domain knowledge based or AI driven based.

4. The apparatus of claim 1, wherein the corrective actions module is at least one of domain knowledge based or AI driven based.

5. The apparatus of claim 1, wherein the simulation module is configured to receive at least one of telemetry data, site and device parameters, tariff data, or forecast data.

6. The apparatus of claim 1, wherein the anomaly detection module is configured to detect at least one of meter anomalies, microinverter anomalies, PV anomalies, Battery anomalies and/or site settings anomalies.

7. The apparatus of claim 6, wherein the corrective mechanisms can comprise changing a current transformer polarity for meter anomalies, determining if a DC switch is on for Battery anomalies, changing power export limit for PV anomalies, or changing breaker ratings for site settings anomalies.

8. The apparatus of claim 1, further comprising a monitoring dashboard that is configured to receive an input from at least one of the simulation module, the anomaly detection module, or the corrective actions module.

9. The apparatus of claim 8, wherein the input from the simulation module comprises key performance indicators (KPIs).

10. The apparatus of claim 8, wherein the input from the anomaly detection module comprises at least one of negative consumption/energy imbalance; site status error including at least one of battery SoC missing, micro issue, battery issue, gateway issue, system controller issue, or dc switch off manually; high/low soc; breaker issue comprising wrong pcs breaker sizing; SoH issue; Discharge (DG) inadequate; photovoltaic (PV) curtailment; recommended for SC+DTG; or forecast error.

11. The apparatus of claim 8, wherein the input from the corrective actions module comprises at least one of fix consumption/battery current transformer (CT) issues; customer experience (CX) team should assist a customer in resolving device-level issues; fix battery issue; correct pcs settings; correct SoH value through calibration; fix communication issue between IoT devices and Cloud change power export limit (PEL) settings higher than zero; change profile to self-consumption from AI optimization mode; or improve accuracy of forecasts.

12. A method for monitoring fleet data, comprising:
emulating site behavior for home energy management system (HEMS) profiles;
detecting an anomaly at the site; and
providing corrective mechanisms to a user for the anomaly.

13. The method of claim 12, further comprising assigning a work order to a respective team.

14. The method of claim 12, wherein detecting the anomaly is performed by an anomaly detection module that is at least one of domain knowledge based, or AI driven based.

15. The method of claim 12, wherein providing the corrective mechanisms is performed by a corrective actions module that is at least one of domain knowledge based, or AI driven based.

16. The method of claim 12, wherein emulating site behavior comprises receiving at least one of telemetry data, site and device parameters, tariff data, or forecast data.

17. The method of claim 12, wherein detecting the anomaly comprises detecting at least one of meter anomalies, microinverter anomalies, PV anomalies, Battery anomalies and/or site settings anomalies.

18. The method of claim 17, wherein providing corrective mechanisms comprises changing a current transformer polarity for meter anomalies, determining if a DC switch is on for Battery anomalies, changing power export limit for PV anomalies, or changing breaker ratings for site settings anomalies.

19. The method of claim 12, further comprising receiving an input from at least one of a simulation module, an anomaly detection module, or a corrective actions module.

20. A non-transitory computer readable storage medium having instructions stored thereon that when executed by a processor perform a method for monitoring fleet data, comprising:
emulating site behavior for home energy management system (HEMS) profiles;
detecting an anomaly at the site; and
providing corrective mechanisms to a user for the anomaly.
